(19) United States
(12) Patent Application Publication
(10) Pub. No.: US 2013/0095637 A1
(43) Pub. Date: Apr. 18, 2013

(54) METHOD OF FABRICATING A SEMICONDUCTOR DEVICE

(71) Applicants: Honggun KIM, Hwaseong-si (KR); Seung-Heon Lee, Seoul (KR); Mansug Kang, Suwon-si (KR); ByeongJu Bae, Hwaseong-Si (KR); Eunkee Hong, Seongnam-si (KR)

(72) Inventors: Honggun KIM, Hwaseong-si (KR); Seung-Heon Lee, Seoul (KR); Mansug Kang, Suwon-si (KR); ByeongJu Bae, Hwaseong-Si (KR); Eunkee Hong, Seongnam-si (KR)

(21) Appl. No.: 13/586,325

(22) Filed: Aug. 15, 2012

(30) Foreign Application Priority Data
Oct. 18, 2011 (KR) 10-2011-0106534

(51) Int. Cl. H01L 21/762

(52) U.S. Cl. 438/435; 257/E21.546

(57) ABSTRACT

A method of fabricating a semiconductor device, the method including forming a mask layer on a semiconductor substrate; forming a trench in the semiconductor substrate using the mask layer as an etch mask; forming a first layer in the trench; and performing a first thermal treatment process on the first layer such that the first thermal treatment process is performed under an atmosphere that includes ozone and water vapor and transforms the first layer into a second layer.

### CROSS-REFERENCE TO RELATED APPLICATIONS

Korean Patent Application No. 10-2011-0106534, filed on Oct. 18, 2011, in the Korean Intellectual Property Office and entitled, “Methods of Fabricating a Semiconductor Device” is hereby incorporated by reference in its entirety.

### BACKGROUND

1. Field

Embodiments relate to a method of fabricating a semiconductor device.

2. Description of the Related Art

As semiconductor devices are scaled down, technologies for increasing an integration density of the semiconductor devices have been considered. For example, a shallow trench isolation (STI) process may be used to electrically and physically separate semiconductor elements (e.g., transistors) from each other. The shallow trench isolation process may include forming a trench in an isolation region of a semiconductor substrate and filling the trench with an insulation layer such as a silicon oxide layer.

### SUMMARY

Embodiments are directed to a method of fabricating a semiconductor device.

The embodiments may be realized by providing a method of fabricating a semiconductor device, the method including forming a mask layer on a semiconductor substrate; forming a trench in the semiconductor substrate using the mask layer as an etch mask; forming a first layer in the trench; and performing a first thermal treatment process on the first layer such that the first thermal treatment process is performed under an atmosphere that includes ozone and water vapor and transforms the first layer into a second layer.

The first layer may be a polysilazane (PSZ) layer.

The second layer may be a silicon oxide layer.

Forming the first layer may include coating a perhydro-polysilazane ((SiH₂NH)ₙ) solution on an entire surface of the substrate having the trench; and removing a solvent in the coated perhydro-polysilazane ((SiH₂NH)ₙ) solution to form a polysilazane layer.

The method may further include forming a thermal oxide layer on a bottom surface and sidewalls of the trench such that forming the thermal oxide layer includes thermally oxidizing the semiconductor substrate using an in-situ steam generation method or using oxygen radicals.

The ozone and then the water vapor may be sequentially supplied during the first thermal treatment process.

The water vapor and then the ozone may be sequentially supplied during the first thermal treatment process.

The atmosphere of the first thermal treatment process may further include ammonia.

The first thermal treatment process may be performed in a chamber at a temperature of about 100° C. to about 500° C. and under a pressure of about 50 torr to about 600 torr.

The method may further include performing a second thermal treatment process on the second layer after the first thermal treatment process such that the second thermal treatment process is performed under another atmosphere including at least one of nitrogen gas, water vapor, and oxygen gas.

The method may further include planarizing the second layer to expose the semiconductor substrate after the second thermal treatment process such that planarizing the second layer includes performing a chemical mechanical polishing process and the mask layer is removed during the chemical mechanical polishing process.

The method may further include planarizing the second layer to expose the semiconductor substrate prior to performing the second thermal treatment process such that planarizing the second layer includes performing a chemical mechanical polishing process and the mask layer is removed during the chemical mechanical polishing process.

The embodiments may also be realized by providing a method of fabricating a semiconductor device, the method including providing a semiconductor substrate; forming a mask layer on the semiconductor substrate; forming a trench in the semiconductor substrate using the mask layer as an etch mask; forming a coating material in the trench; and performing a thermal treatment process on the coating material such that the thermal treatment process is performed under an atmosphere that includes ozone and water vapor and transforms the coating material into an insulation layer.

The coating material may include a polysilazane (PSZ) layer, and the insulation layer may include a silicon oxide layer.

The atmosphere of the thermal treatment process may further include ammonia.

The ammonia may be supplied at a flow rate of about 1,000 sccm to about 10,000 sccm.

The ozone may be supplied at a flow rate of about 10,000 to about 30,000 milligrams per minute, and the water vapor may be supplied at a flow rate of about 100 to about 1,000 milligrams per minute.

The method may further include performing another thermal treatment process on the insulation layer after the one thermal treatment process such that the other thermal treatment process is performed under an inert atmosphere or an oxidizing atmosphere.

The method may further include planarizing the insulation layer to expose the semiconductor substrate after the other thermal treatment process such that planarizing the insulating layer includes performing a chemical mechanical polishing process in which the mask layer is removed and such that the insulation layer becomes an isolating insulation layer remaining in the trench.

The method may further include planarizing the insulation layer to expose the semiconductor substrate prior to performing the other thermal treatment process such that planarizing the insulation layer includes performing a chemical mechanical polishing process in which the mask layer is removed and such that the insulation layer becomes an isolating insulation layer remaining in the trench.

### BRIEF DESCRIPTION OF THE DRAWINGS

Features will become apparent to those of ordinary skill in the art by describing in detail exemplary embodiments with reference to the attached drawings in which:

FIG. 1 illustrates a cross sectional view of a semiconductor device fabricated according to an embodiment.

FIGS. 2 to 8 illustrate cross sectional views of stages in a method of fabricating an isolating insulation layer of a semiconductor device according to an embodiment.

FIGS. 9 to 13 illustrate cross sectional views of stages in a method of fabricating an isolating insulation layer of a semiconductor device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

Moreover, it will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts.

As used herein the term “and/or” includes any and all combinations of one or more of the associated listed items. Exemplary embodiments explained and illustrated herein include their complementary counterparts.

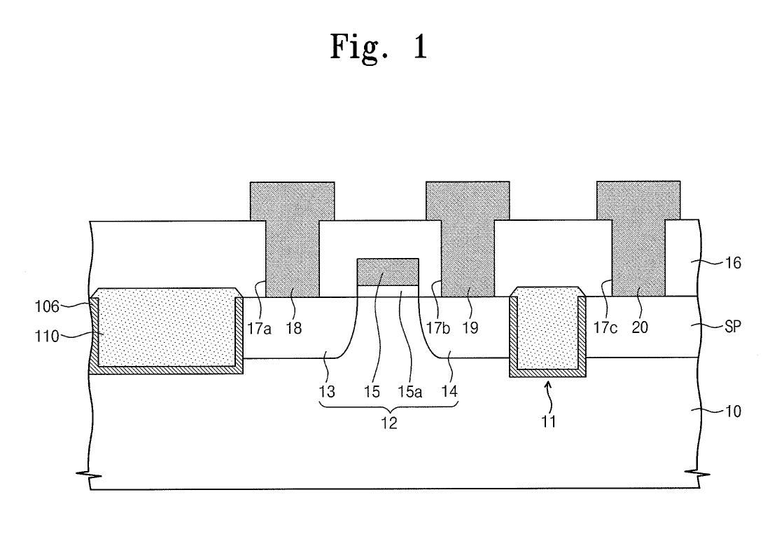

FIG. 1 illustrates a cross sectional view of a semiconductor device fabricated according to an embodiment.

Referring to FIG. 1, an isolation structure 11 (for defining active regions) may be formed in a semiconductor substrate 10, e.g., a silicon substrate. In an implementation, the isolation structure 11 may have a shallow trench isolation (STI) structure. For example, the isolation structure 11 may fill a trench that is formed in the semiconductor substrate 10. The isolation structure 11 may have different widths according to a position thereof.

The isolation structure 11 may include an isolating insulation layer 110. The isolating insulation layer 110 may be or include a silicon oxide (SiO₂) layer. A thermal oxide layer 106 may be disposed between the isolating insulation layer 110 and the semiconductor substrate 10.

A discrete device 12, e.g., a metal-oxide-semiconductor (MOS) transistor may be disposed in and on any one of the active regions. The MOS transistor may include a source region 13, a drain region 14, and a gate electrode 15. A gate oxide layer 15a may be disposed on the semiconductor substrate 10 between the source and drain regions 13 and 14. The gate oxide layer 15a may be between the semiconductor substrate 10 and the gate electrode 15. The gate electrode 15, the isolation structure 11, and the source/drain regions 13 and 14 may be covered with an interlayer insulation layer 16.

A substrate pick-up region SP may be disposed in another active region adjacent to the MOS transistor 12. The substrate pick-up region SP may include an impurity region having a same conductivity type as the semiconductor substrate 10. First to third contact holes 17a, 17b, and 17c may penetrate the interlayer insulation layer 16. The first to third contact holes 17a, 17b, and 17c may expose portions of the source region 13, the drain region 14, and the substrate pick-up region SP, respectively. The first to third contact holes 17a, 17b, and 17c may be filled to form a source electrode 18, a drain electrode 19, and a substrate pick-up electrode 20, respectively. A plurality of interconnection lines, a passivation layer, and pads (not illustrated) may be disposed on the substrate including the electrodes 18, 19, and 20, thereby forming a semiconductor device.

As the semiconductor device becomes more highly integrated, an aspect ratio of the trench may also be increased. For example, if the isolating insulation layer 110 is formed using a flowable material layer, the flowable material layer in the narrow and deep trench, i.e., the trench having the high aspect ratio, may not be completely cured and may have an unstable property, even if an annealing process is performed on the flowable material layer. Thus, when the cured fiowable material layer is planarized using a subsequent chemical mechanical polishing (CMP) process, some defects may be present after the plazarization process.

Accordingly, the embodiments provide a method of fabricating a stable and reliable insulation layer constituting the isolation structure. The embodiments will be described more fully hereinafter.

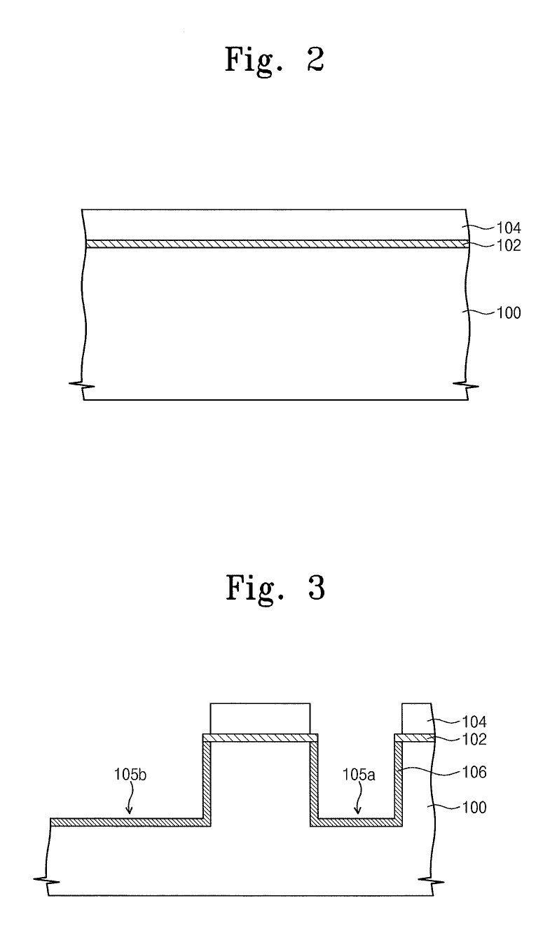

FIGS. 2 to 8 illustrate cross sectional views of stages in a method of fabricating an isolating insulation layer of a semiconductor device according to an embodiment.

Referring to FIG. 2, a mask layer 104 may be formed on a semiconductor substrate 100. The mask layer 104 may include, e.g., a silicon nitride layer. A buffer layer 102 (formed of, e.g., silicon oxide) may be formed between the semiconductor substrate 100 and the mask layer 104. The buffer layer 102 and the mask layer 104 may each be formed using, e.g., a chemical vapor deposition (CVD) process. For example, the mask layer 104 may be formed using a low pressure chemical vapor deposition (LPCVD) process. In an implementation, the buffer layer 102 may have a thickness of, e.g., about 4 nanometers (nm), and the mask layer 104 may have a thickness of, e.g., about 200 nanometers (nm).

Referring to FIG. 3, the mask layer 104 may be patterned to define exposure regions on the semiconductor substrate 100. A first trench 105a and a second trench 105b may be formed in the semiconductor substrate 100 using the patterned mask layer 104 as an etch mask. In an implementation, the first trench 105a may have a width different from the second trenches 105b. The first and second trenches 105a and 105b may be formed by etching the buffer layer 102 and the semiconductor substrate 100 using the patterned mask layer 104 as an etch mask. In an implementation, the mask layer 104 may be patterned using a photolithography process, and the first and second trenches 105a and 105b may be formed using a dry etching process, e.g., a reactive ion etching (RIE) process. The first and second trenches 105a and 105b may define active regions.

In an implementation, the first and second trenches 105a and 105b may each have a width of about 100 nanometers (nm) and a depth of about 300 nanometers (nm). In an implementation, another silicon oxide layer may be additionally formed on the mask layer 104. In this case, the other silicon oxide layer may be patterned, and the first and second trenches 105a and 105b may be formed using the patterned silicon oxide layer as an etch mask.

A thermal oxide layer 106 may be formed on bottom surfaces and side walls of the first and second trenches 105a and 105b. In an implementation, the thermal oxide layer 106 may be formed by oxidizing the semiconductor substrate 100 using a thermal oxidation process. The thermal oxidation process may be performed using an in-situ steam generation (ISSG) technique, and the bottom surfaces and side walls of the first and second trenches 105a and 105b may be oxidized during the thermal oxidation process. In an implementation, the thermal oxide layer 106 may be formed to a thickness of about 3 nanometers (nm). In an implementation, the thermal oxide layer 106 may be formed using oxygen radicals.

Subsequently, the patterned mask layer 104 may be isotropically etched to increase upper widths of the trenches 105a and 105b. In an implementation, the isotropic etching process may be performed such that the upper widths of the trenches 105a and 105b are increased by about 10 nanometers on each side thereof. The isotropic etching process may be performed using an etchant that exhibits an etch selectivity with respect to the buffer layer 102. Accordingly, effective aspect ratios of the trenches 105a and 105b may be reduced. As a result of the isotropic etching process, filling of the trenches 105a and 105b with a coating material provided in a subsequent process may be facilitated.

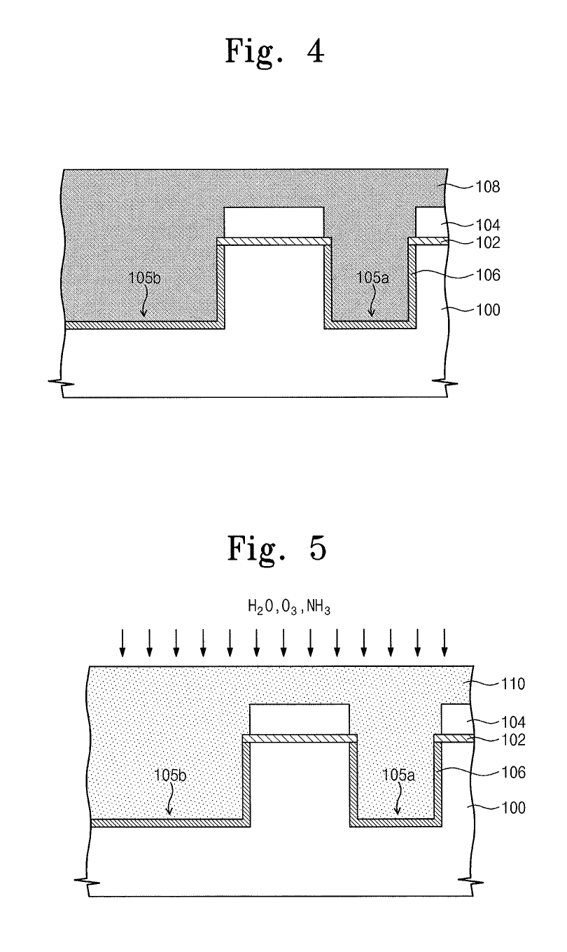

Referring to FIG. 4, a coating material 108 may be formed on an entire surface of the substrate 100 including the trenches 105a and 105b and/or the thermal oxide layer 106. The coating material 108 may be formed of or may include a flowable material to completely fill the trenches 105a and 105b without any voids. The coating material 108 may include a polysilazane (PSZ) layer. For example, the coating material 108 may be formed by coating a perhydro-polysilazane ((SiH₂NH)ₙ) solution on an entire surface of the substrate including the trenches 105a and 105b and/or the thermal oxide layer 106.

In an implementation, the coating material 108 may have a thickness of about 600 nanometers on the patterned mask layer 104 (formed of e.g., a silicon nitride layer). In the event that the coating material 108 is formed of a polysilazane (PSZ) layer, the polysilazane (PSZ) layer may be formed by coating a perhydro-polysilazane ((SiH₂NH)ₙ) solution on an entire surface of the substrate 100 using, e.g., a spin coating method, and by baking the coated perhydro-polysilazane ((SiH₂NH)ₙ) solution to remove a solvent in the coated perhydro-polysilazane ((SiH₂NH)ₙ) solution. In an implementation, the coated perhydro-polysilazane ((SiH₂NH)ₙ) solution may be baked or cured at a temperature of about 150° C. for about 3 minutes.

Referring to FIG. 5, a first thermal treatment process may be performed on the coating material 108. As a result of the first thermal treatment process, the coating material 108 may be changed into an insulation layer 110. For example, if the coating material 108 is formed of a polysilazane (PSZ) layer, the polysilazane (PSZ) layer may be transformed into a silicon oxide layer by the first thermal treatment process.

In an implementation, the first thermal treatment process may be performed under an atmosphere including, e.g., a mixture of ozone (O₃) and water vapor. In an implementation, ozone and then water vapor may be sequentially supplied during the first thermal treatment process. In an implementation, water vapor and then ozone may be sequentially supplied during the first thermal treatment process. The first thermal treatment process may be performed in a chamber at a temperature of about 100° C. to about 500° C. and under a pressure of about 50 torr to about 600 torr. During the first thermal treatment process, the water vapor may be supplied at a flow rate of about 100 milligrams per minute (mgm) to about 1,000 mgm, and the ozone (O₃) may be supplied at a flow rate of about 10,000 mgm to about 30,000 mgm. In an implementation, the atmosphere may further include an ammonia (NH₃) gas during the first thermal treatment process. The ammonia (NH₃) gas may be supplied at a flow rate of about 1,000 standard cubic centimeters per minute (sccm) to about 10,000 sccm. The first thermal treatment process may be performed using a pyrogenic oxidation method with water vapor having a relatively high concentration. Such a method may facilitate transforming the polysilazane (PSZ) layer into the silicon oxide layer.

As described above, the first thermal treatment process may transform the coating material 108 into the insulation layer 110. The insulation layer 110 may have excellent strength or resistance against a chemical mechanical polishing (CMP) process, which is performed in a subsequent step. As described above, the first thermal treatment process may be performed at a temperature of about 500° C. or less. Thus, the first thermal treatment process may help prevent excessive shrinking of the coating material 108. Accordingly, an entire portion of the coating material 108 may be uniformly transformed into the insulation layer 110 during the first thermal treatment process.

As described above, after the coating material 108 is formed of a polysilazane (PSZ) layer, the polysilazane (PSZ) layer may be fully transformed into the silicon oxide layer by the first thermal treatment. To fully transform the polysilazane (PSZ) layer into the silicon oxide layer, sufficient oxygen should be supplied during the first thermal treatment. A chemical reaction of the transformation may be expressed by the following Chemical Formula 1.

SiH₂NH+O₂→SiO₂+NH₃ (volatile) [Chemical Formula 1]

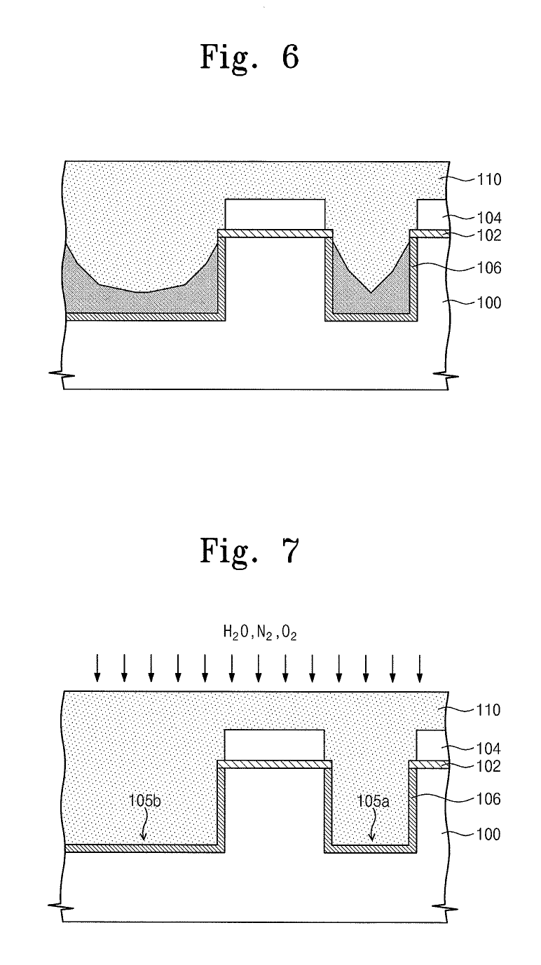

As expressed by the above Chemical Formula 1, the polysilazane (PSZ) layer may react with the oxygen gas to form the silicon oxide layer. For example, supplying a sufficient amount of the oxygen gas may help ensure that all of the coating material 108 is transformed into the insulation layer 110. Otherwise, some portions of the coating material 108 may exist without any change or transformation even after the first thermal treatment process is performed, as illustrated in FIG. 6. In this case, if a chemical mechanical polishing (CMP) process were to be performed the insulation layer 110, the insulation layer 110 may not be uniformly planarized, and process defects may be generated. This may be due to a difference between a polishing rate of the insulation layer 110 and a polishing rate of the coating material 108.

Accordingly, the first thermal treatment process may be performed under an atmosphere including, e.g., ozone and water vapor to provide a sufficient hydrophilic environment. Thus, the coating material 108 (e.g., the polysilazane (PSZ) layer) may sufficiently react with oxygen, and the coating material 108 (e.g., the polysilazane (PSZ) layer) may be fully transformed into the insulation layer 110 (e.g., the silicon oxide layer). Accordingly, the first thermal treatment process may help improve efficiency of the transformation of the coating material 108 into the insulation layer 110.

Referring to FIG. 7, a second thermal treatment process may be performed on the substrate 100 including the insulation layer 110 (e.g., the silicon oxide layer). The second thermal treatment process may be performed under an oxidation gas atmosphere and/or an inert gas atmosphere. For example, the second thermal treatment process may be performed under an atmosphere including at least one of nitrogen gas, water vapor, and oxygen gas.

In an implementation, the second thermal treatment process may be performed in a furnace. For example, the second thermal treatment process may be performed at a temperature of about 800° C. to about 1,100° C. for about 30 minutes. The second thermal treatment process may remove ammonia (NH₃) and moisture remaining in the insulation layer 110 (e.g., the silicon oxide layer). For example, the insulation layer 110 (e.g., the silicon oxide layer) may be condensed by the second thermal treatment process. Thus, the second thermal treatment process may help improve a leakage current characteristic of the insulation layer 110 (e.g., the silicon oxide layer).

If the second thermal treatment process is performed under an inert gas atmosphere, e.g., a nitrogen gas, oxidation of sidewalls of the trenches 105a and 105b may be suppressed. Thus, the second thermal treatment process may help prevent effective widths of the trenches 105 and 105b from being increased. For example, in the event that the second thermal treatment process is performed under an inert gas atmosphere, e.g., a nitrogen gas, widths of the active regions may not be reduced. In an implementation, the second thermal treatment process may be performed using a rapid thermal annealing (RTA) process or a rapid thermal oxidation (RTO) process.

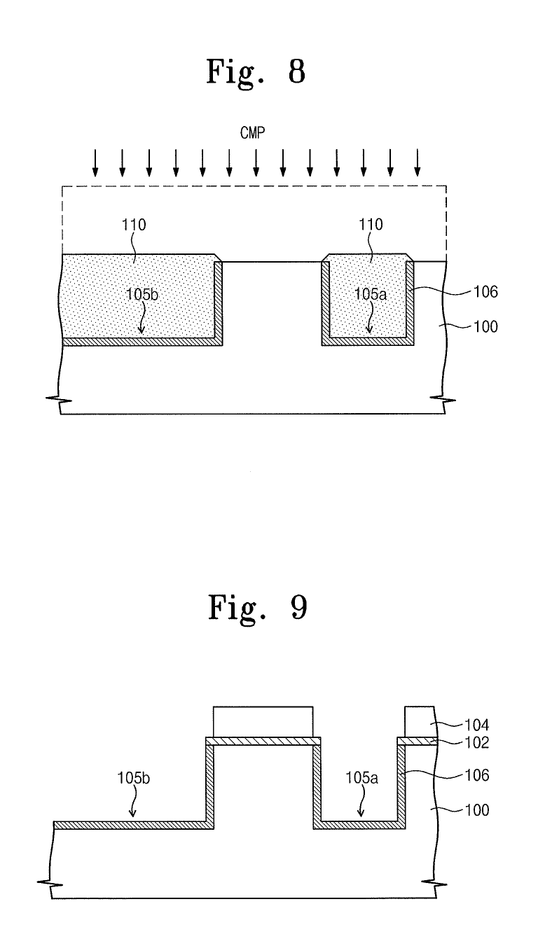

Referring to FIG. 8, a polishing process may be performed on the insulation layer 110. The polishing process may include, e.g., a chemical mechanical polishing (CMP) process. As a result of the polishing process, the buffer layer 102 and the mask layer 104 may be removed to expose the active regions. A polishing rate of the polishing process may be controlled by adjusting a pressure of the substrate 100 applied to a polishing pad of a CMP apparatus used in the CMP process. As a result of the polishing process, the insulation layer 110 may be planarized to form an isolating insulation layer 110 in the trenches 105a and 105b.

Subsequently, referring again to FIG. 1, a discrete device 12, e.g., a metal-oxide-semiconductor (MOS) transistor, may be formed in and on any one of the active regions. The MOS transistor 12 may include the source region 13, the drain region 14, and the gate electrode 15. The gate oxide layer 15a may be formed on the semiconductor substrate 10 between the source and drain regions 13 and 14. The gate oxide layer 15a may be formed between the semiconductor substrate and the gate electrode 15. The gate electrode 15, the isolating insulation layer 110, and the source/drain regions 13 and 14 may be covered with the interlayer insulation layer 16. Further, the substrate pick-up region SP may be formed in another active region adjacent to the MOS transistor 12. For example, the substrate pick-up region SP may be an impurity region having the same conductivity type as the semiconductor substrate. The first to third contact holes 17a, 17b, and 17c may be formed to penetrate the interlayer insulation layer 16. The first to third contact holes 17a, 17b, and 17c may expose portions of the source region 13, the drain region 14, and the substrate pick-up region SP, respectively. The first to third contact holes 17a, 17b, and 17c may be filled to form the source electrode 18, the drain electrode 19, and the substrate pick-up electrode 20, respectively. The plurality of interconnection lines, the passivation layer, and the pads (not illustrated) may be formed on the substrate 10 including the electrodes 18, 19, and 20, thereby forming the semiconductor device.

FIGS. 9 to 13 illustrate cross sectional views of stages in a method of fabricating an isolating insulation layer of a semiconductor device according to an embodiment. For the purpose of ease and convenience in explanation, repeated descriptions of the same components as illustrated in the previous embodiment may be omitted or only briefly mentioned.

Referring to FIG. 9, a buffer layer 102 (formed of, e.g., silicon oxide) and a mask layer 104 may be sequentially formed on a semiconductor substrate 100. A first trench 105a and a second trench 105b may be formed in the semiconductor substrate 100 in the same manner as described with reference to FIGS. 1 to 3. In an implementation, the first trench 105a may have a width different from that of the second trench 105b. A thermal oxide layer 106 may be formed on bottom surfaces and side walls of the first and second trenches 105a and 105b.

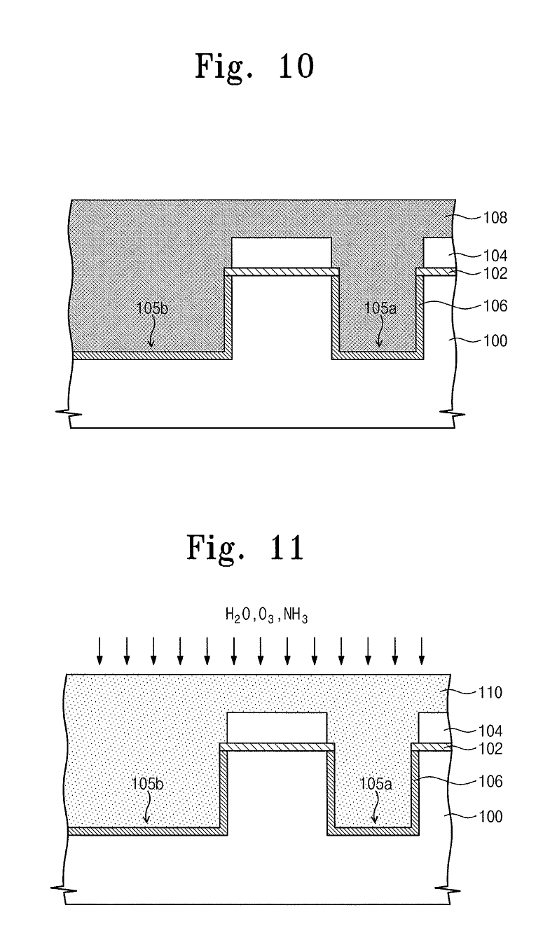

Referring to FIG. 10, a coating material 108 may be formed on an entire surface of the substrate 100 including the trenches 105a and 105b and the thermal oxide layer 106. The coating material 108 may completely fill the trenches 105a and 105b without any voids. The coating material 108 may include a polysilazane (PSZ) layer. In an implementation, the coating material 108 may be formed by coating a perhydro-polysilazane ((SiH₂NH)ₙ) solution on an entire surface of the substrate using, e.g., a spin coating method, and baking the coated perhydro-polysilazane ((SiH₂NH)ₙ) solution to remove a solvent in the coated perhydro-polysilazane ((SiH₂NH)ₙ) solution. In an implementation, the coated perhydro-polysilazane ((SiH₂NH)ₙ) solution may be baked or cured at a temperature of about 150° C. for about 3 minutes.

Referring to FIG. 11, a first thermal treatment process may be performed on the coating material 108. As a result of the first thermal treatment process, the coating material 108 may be changed into an insulation layer 110. For example, if the coating material 108 is formed of a polysilazane (PSZ) layer, the polysilazane (PSZ) layer may be transformed into a silicon oxide layer by the first thermal treatment process.

In an implementation, the first thermal treatment process may be performed under an atmosphere including a mixture of ozone (O₃) and water vapor. In an implementation, ozone and then water vapor may be sequentially supplied during the first thermal treatment process. In an implementation, water vapor and then ozone may be sequentially supplied during the first thermal treatment process. The first thermal treatment process may be performed in a chamber at a temperature of, e.g., about 100° C. to about 500° C., and under a pressure of, e.g., about 50 torr to about 600 torr. During the first thermal treatment process, the water vapor may be supplied at a flow rate of, e.g., about 100 milligrams per minute (mgm) to about 1,000 mgm, and the ozone (O₃) may be supplied at a flow rate of, e.g., about 10,000 mgm to about 30,000 mgm. In an implementation, the atmosphere may further include an ammonia (NH₃) gas during the first thermal treatment process. The ammonia (NH₃) gas may be supplied at a flow rate of about 1,000 standard cubic centimeters per minute (sccm) to about 10,000 sccm.

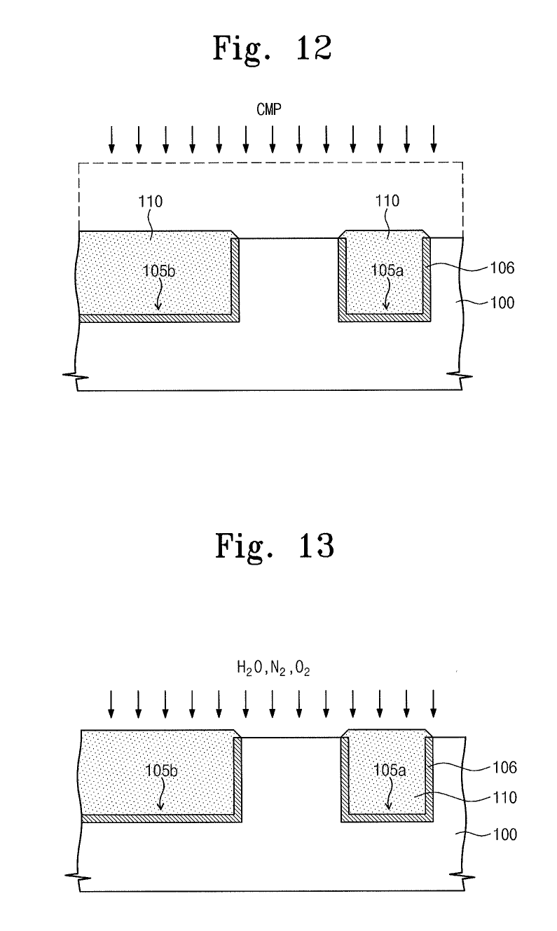

Referring to FIG. 12, a polishing process may be performed on the insulation layer 110 after the first thermal treatment process. The polishing process may include, e.g., a chemical mechanical polishing (CMP) process. As a result of the polishing process, the buffer layer 102 and the mask layer 104 may be removed to expose the active regions.

Referring to FIG. 13, a second thermal treatment process may be performed on the substrate 100 after the polishing process is performed. The second thermal treatment process may be performed under an oxidation gas atmosphere and/or an inert gas atmosphere. For example, the second thermal treatment process may be performed under an atmosphere including at least one of nitrogen gas, water vapor, and oxygen gas. In an implementation, the second thermal treatment process may be performed at a temperature of about 800° C. to about 1,100° C. for about 30 minutes.

The polishing process may remove the mask layer 104 (and the buffer layer 102) prior to performing the second thermal treatment process, unlike the previous embodiment. For example, the second thermal treatment process may be performed under an oxidation gas atmosphere and/or an inert gas atmosphere after planarization of the insulation layer 110, thereby more effectively removing ammonia (NH₃) and moisture remaining in the planarized insulation layer 110 (e.g., the silicon oxide layer) through interfaces between the planarized insulation layer 110 and the thermal oxide layer 106 (or the substrate 100). Thus, densification or condensing of the insulation layer 110 may be more efficiently accelerated. Accordingly, leakage current characteristic of the insulation layer 110 may be significantly improved. As a result of the second thermal treatment process, the planarized insulation layer 110 may be condensed to a greater degree to form a dense isolating insulation layer 110 in the trenches 105a and 105b.

Subsequently, referring again to FIG. 1, the discrete device 12, e.g., a metal-oxide-semiconductor (MOS) transistor, may be formed in and on any one of the active regions. The MOS transistor 12 may include the source region 13, the drain region 14, and the gate electrode 15. The gate oxide layer 15a may be formed on the semiconductor substrate between the source and drain regions 13 and 14. The gate oxide layer 15a may be formed between the semiconductor substrate 10 and the gate electrode 15. The gate electrode 15, the isolating insulation layer 110, and the source/drain regions 13 and 14 may be covered with the interlayer insulation layer 16. Further, the substrate pick-up region SP may be formed in another active region adjacent to the MOS transistor 12. The substrate pick-up region SP may be an impurity region having the same conductivity type as the semiconductor substrate 10. The first to third contact holes 17a, 17b, and 17c may be formed to penetrate the interlayer insulation layer 16. The first to third contact holes 17a, 17b, and 17c may expose portions of the source region 13, the drain region 14, and the substrate pick-up region SP, respectively. The first to third contact holes 17a, 17b, and 17c may be filled to form the source electrode 18, the drain electrode 19, and the substrate pick-up electrode 20, respectively. The plurality of interconnection lines, the passivation layer, and the pads (not illustrated) may be disposed on the substrate including the electrodes 18, 19, and 20, thereby forming a semiconductor device.

By way of summation and review, a tetraethyl orthosilicate (TEOS) layer may be used as an insulation layer of the semiconductor devices. However, when the TEOS layer is formed in a groove or a trench having a high aspect ratio, voids or seams may be formed in the TEOS layer. In order to help prevent the voids or the seams from being formed in the groove or the trench, a flowable material may be coated on the semiconductor substrate including the groove or the trench. The flowable material may be annealed or cured to form an oxide layer. If the aspect ratio of the groove or the trench is too high, the flowable material in the groove or the trench may not be fully cured. Thus, even though the flowable material is used in formation of the insulation layer filling the groove or the trench, there may be some difficulty in transforming the flowable material into an oxide layer.

The embodiments provide a method of fabricating a semiconductor device having an insulation layer in a manner that may surmount the foregoing challenges.

According to the embodiments set forth above, a coating material may be formed in a trench for isolating semiconductor elements, e.g., MOS transistors, from each other. The coating material may be transformed into an insulation layer, e.g., a silicon oxide layer, through a first thermal treatment process. The first thermal treatment process may be performed under an atmosphere including a mixture of ozone (O₃) and water vapor. Thus, sufficient oxygen may be supplied during the first thermal treatment process, thereby helping to ensure a full transformation of, e.g., a polysilazane layer (used as the coating material), into a silicon oxide layer. Accordingly, the first thermal treatment process may help improve the efficiency of the transformation of the polysilazane layer into the silicon oxide layer. In addition, even when a CMP process is performed on the silicon oxide layer (annealed by the first thermal treatment process), generation of process defects may be reduced and/or prevented because the polysilazane layer may be fully transformed into the silicon oxide layer through the first thermal treatment process.

In addition, a second thermal treatment may be additionally performed on the silicon oxide layer after the first thermal treatment process or the polishing process. Thus, the silicon oxide layer may be condensed to a greater degree and may have an improved leakage current characteristic.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of fabricating a semiconductor device, the method comprising:
forming a mask layer on a semiconductor substrate;
forming a trench in the semiconductor substrate using the mask layer as an etch mask;
forming a first layer in the trench; and
performing a first thermal treatment process on the first layer such that the first thermal treatment process is performed under an atmosphere that includes ozone and water vapor and transforms the first layer into a second layer.

2. The method as claimed in claim 1, wherein the first layer is a polysilazane (PSZ) layer.

3. The method as claimed in claim 1, wherein the second layer is a silicon oxide layer.

4. The method as claimed in claim 1, wherein forming the first layer includes:
coating a perhydro-polysilazane ((SiH₂NH)ₙ) solution on an entire surface of the substrate having the trench; and
removing a solvent in the coated perhydro-polysilazane ((SiH₂NH)ₙ) solution to form a polysilazane layer.

5. The method as claimed in claim 1, further comprising forming a thermal oxide layer on a bottom surface and sidewalls of the trench such that forming the thermal oxide layer includes thermally oxidizing the semiconductor substrate using an in-situ steam generation method or using oxygen radicals.

6. The method as claimed in claim 1, wherein the ozone and then the water vapor are sequentially supplied during the first thermal treatment process.

7. The method as claimed in claim 1, wherein the water vapor and then the ozone are sequentially supplied during the first thermal treatment process.

8. The method as claimed in claim 1, wherein the atmosphere of the first thermal treatment process further includes ammonia.

9. The method as claimed in claim 1, wherein the first thermal treatment process is performed in a chamber at a temperature of about 100° C. to about 500° C. and under a pressure of about 50 torr to about 600 torr.

10. The method as claimed in claim 1, further comprising performing a second thermal treatment process on the second layer after the first thermal treatment process such that the second thermal treatment process is performed under another atmosphere including at least one of nitrogen gas, water vapor, and oxygen gas.

11. The method as claimed in claim 10, further comprising planarizing the second layer to expose the semiconductor substrate after the second thermal treatment process such that planarizing the second layer includes performing a chemical mechanical polishing process and the mask layer is removed during the chemical mechanical polishing process.

12. The method as claimed in claim 10, further comprising planarizing the second layer to expose the semiconductor substrate prior to performing the second thermal treatment process such that planarizing the second layer includes performing a chemical mechanical polishing process and the mask layer is removed during the chemical mechanical polishing process.

13. A method of fabricating a semiconductor device, the method comprising:
providing a semiconductor substrate;
forming a mask layer on the semiconductor substrate;
forming a trench in the semiconductor substrate using the mask layer as an etch mask;
forming a coating material in the trench; and
performing a thermal treatment process on the coating material such that the thermal treatment process is performed under an atmosphere that includes ozone and water vapor and transforms the coating material into an insulation layer.

14. The method as claimed in claim 13, wherein:
the coating material includes a polysilazane (PSZ) layer, and
the insulation layer includes a silicon oxide layer.

15. The method as claimed in claim 13, wherein the atmosphere of the thermal treatment process further includes ammonia.

16. The method as claimed in claim 15, wherein the ammonia is supplied at a flow rate of about 1,000 sccm to about 10,000 sccm.

17. The method as claimed in claim 13, wherein:
the ozone is supplied at a flow rate of about 10,000 to about 30,000 milligrams per minute, and
the water vapor is supplied at a flow rate of about 100 to about 1,000 milligrams per minute.

18. The method as claimed in claim 13, further comprising performing another thermal treatment process on the insulation layer after the one thermal treatment process such that the other thermal treatment process is performed under an inert atmosphere or an oxidizing atmosphere.

19. The method as claimed in claim 18, further comprising planarizing the insulation layer to expose the semiconductor substrate after the other thermal treatment process such that planarizing the insulating layer includes performing a chemical mechanical polishing process in which the mask layer is removed and such that the insulation layer becomes an isolating insulation layer remaining in the trench.

20. The method as claimed in claim 18, further comprising planarizing the insulation layer to expose the semiconductor substrate prior to performing the other thermal treatment process such that planarizing the insulation layer includes performing a chemical mechanical polishing process in which the mask layer is removed and such that the insulation layer becomes an isolating insulation layer remaining in the trench.
